(19) United States
(12) Patent Application Publication
(10) Pub. No.: US 2025/0226203 A1
(43) Pub. Date: Jul. 10, 2025

(54) ENHANCED DEUTERIUM MIGRATION

(71) Applicant: Applied Materials, Inc., Santa Clara, CA (US)

(72) Inventors: Madhu Santosh Kumar Mutyala, San Jose, CA (US); Hang Yu, San Jose, CA (US); Woongsik Nam, Santa Clara, CA (US); Deenesh Padhi, Saratoga, CA (US)

(73) Assignee: Applied Materials, Inc., Santa Clara, CA (US)

(21) Appl. No.: 18/408,666

(22) Filed: Jan. 10, 2024

(51) Int. Cl. H01L 21/02; H01L 21/822

(52) U.S. Cl. CPC H01L 21/02211; H01L 21/02123; H01L 21/02274; H10D 84/038; H10D 88/01

(57) ABSTRACT

Embodiments of the present technology may include semiconductor processing methods and systems. Methods include flowing a deuterium-containing precursor and a silicon containing precursor into a processing region of a processing chamber. Methods include contacting a semiconductor device disposed in the processing region with the deuterium-containing precursor and the silicon containing precursor. Methods include forming a deuterium-containing dielectric film over or on the semiconductor device at a processing temperature of greater than or about 350° C. Methods include passivating the target region with deuterium from the deuterium-containing dielectric film. Methods include where the deuterium-containing dielectric film is spaced apart from or adjacent to the target region.

### TECHNICAL FIELD

The present technology relates to semiconductor systems and processes. More specifically, the present technology relates to three-dimensional (3D) semiconductor devices, such as dynamic random-access memory (DRAM) devices (3D DRAM), and methods of forming such devices.

### BACKGROUND

Integrated circuits are made possible by processes which produce intricately patterned material layers on substrate surfaces. Producing patterned material on a substrate requires controlled methods of formation and removal of exposed material. Material characteristics may affect how the device operates and may also affect how the films are removed relative to one another. Reducing the size of integrated circuits (ICs) results in improved performance, increased capacity, and/or reduced cost. Each size reduction requires more sophisticated techniques to form the ICs. Shrinking transistor size, for example, allows for the incorporation of an increased number of memory or logic devices on a chip, lending to the fabrication of products with increased capacity. The drive for ever-more capacity, however, is not without issue. The necessity to optimize the performance of each device becomes increasingly significant. For instance, film modification and passivation become increasing difficult as device size continues to decrease.

Thus, there is a need for improved systems and methods that can be used to produce high quality devices and structures. These and other needs are addressed by the present technology.

### SUMMARY

The present technology is generally directed to systems and methods for semiconductor processing, such as modifying a target region of a substrate. Methods include flowing a deuterium-containing precursor and a silicon containing precursor into a processing region of a processing chamber. Methods include contacting a semiconductor device disposed in the processing region with the deuterium-containing precursor and the silicon-containing precursor. Methods include forming a deuterium-containing dielectric film over or on the semiconductor device at a processing temperature of greater than or about 350° C. Methods include passivating the target region with deuterium from the deuterium-containing dielectric film. Methods include where the deuterium-containing dielectric film is spaced apart from or adjacent to the target region.

In embodiments, the deuterium-containing precursor includes one or more of D₂, D₂O, DH (deuterium-hydrogen) or HDO (deuterium-hydrogen oxide). In more embodiments, the deuterium-containing precursor and the silicon containing precursor are flowed utilizing a plasma process, where the plasma further includes one or more of argon (Ar), helium (He), hydrogen (H₂), nitrogen (N₂), oxygen (O₂), ammonia (NH₃), or nitrogen fluoride (NF₃). Furthermore, in embodiments, the silicon-containing precursor includes one or more of silane (SiH₄), disilane (Si₂H₆), silicon tetrachloride (SiCl₄), trichlorosilane (SiHCl₃), dichlorosilane (SiH₂Cl₂), hexachlorodisilane (Si₂Cl₆), silicon tetrafluoride (SiF₄), silicon tetrabromide (SiBr₄), tetraethyl orthosilicate (TEOS), tris (dimethylamino) silane (TDMAS), bis (t-butylamino) silane (BTBAS), bis(diethylamion)silane (BDEAS), or a combination thereof. In embodiments, the deuterium-containing dielectric film is formed over or on the semiconductor device at a processing temperature of greater than or about 400° C. Additionally or alternatively, the deuterium-containing dielectric film is formed with a ratio of the deuterium-containing precursor to the silicon-containing precursor of greater than or about 0.9:1. In yet further embodiments, the ratio of the deuterium-containing precursor to the silicon-containing precursor of greater than or about 1.5:1. In further embodiments, the ratio of the deuterium-containing precursor to the silicon-containing precursor of greater than or about 4:1. Embodiments include where the deuterium-containing dielectric film contains from about 0.1 wt. % to about 1 wt. % deuterium, based upon the weight of the deuterium-containing dielectric film. In embodiments, the target region includes a channel-gate interface. Moreover, in embodiments, the deuterium-containing dielectric film includes an interlayer dielectric. In further embodiments, the plasma includes a high frequency plasma having a plasma power of greater than or about 800 watts.

The present technology is also generally directed to semiconductor processing methods. Methods include forming a semiconductor device having one or more transistors and one or more capacitors over the one or more transistors in a processing region of a processing chamber. Methods include flowing a deuterium-containing precursor and a silicon-containing precursor into the processing region of the processing chamber. Methods include contacting the semiconductor device disposed in the processing region with the deuterium-containing precursor and the silicon containing precursor. Methods include forming a deuterium-containing dielectric film over or on the semiconductor device at a processing temperature of greater than or about 350° C. Methods include passivating a target region of the semiconductor device with deuterium from the deuterium-containing dielectric film. Methods include where the deuterium-containing dielectric film is spaced apart from or adjacent to the target region.

In embodiments, the semiconductor device includes a three-dimensional (3D) semiconductor device. In more embodiments, the three-dimensional device includes a three-dimensional dynamic random access memory (3D DRAM) device. Furthermore, in embodiments the target region includes a channel-gate interface and the deuterium-containing dielectric film include an interlayer dielectric. Additionally or alternatively, in embodiments, the silicon-containing precursor includes tetraethyl orthosilicate, and where the deuterium-containing dielectric film is formed with a ratio of the deuterium-containing precursor to the silicon-containing precursor of greater than or about 0.9:1. In embodiments, the deuterium-containing precursor and the silicon containing precursor are flowed utilizing a plasma process, where the plasma includes a high frequency plasma having a plasma power of greater than or about 800 watts.

The present technology is also generally directed to methods of forming a three-dimensional dynamic random-access memory (3D DRAM) device. Methods include forming a semiconductor structure including one or more transistors and one or more capacitors over the one or more transistors in a processing region of a processing chamber, where the one or more transistors contains a channel and a gate. Methods include flowing a deuterium-containing precursor and a silicon-containing precursor into the processing region of the processing chamber. Methods include contacting the semiconductor structure disposed in the processing region with the deuterium-containing precursor and the silicon containing precursor. Methods include forming a deuterium-containing dielectric film over or on the semiconductor structure at a processing temperature of greater than or about 350° C. Methods include passivating a channel-gate interface region of the semiconductor structure with deuterium from the deuterium-containing dielectric film. In embodiments, the deuterium-containing dielectric film is an interlayer dielectric overlying the one or more transistors and/or the one or more capacitors.

Such technology may provide numerous benefits over conventional systems and methods of forming 3D devices, such as 3D DRAM devices, in embodiments. For example, by forming devices as discussed herein, increased migration of one or more dopants to a target region may be obtained without requiring increased overall dopant concentration. Thus, devices and methods discussed herein may provide for increased retention time and therefore reliability of the device. Embodiments of the present technology, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing system according to embodiments of the present technology.

FIG. 1B shows a schematic cross-sectional view of an exemplary processing system according to embodiments of the present technology.

FIG. 2 shows a schematic view of an exemplary unit cell according to embodiments of the present technology.

FIG. 3 shows operations of an exemplary method of semiconductor processing according to some embodiments of the present technology.

FIG. 4 shows a schematic cross-sectional view of an exemplary unit cell according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Three dimensional structures, such as dynamic random-access memory (DRAM) devices, including horizontal channel and/or vertical channel device, include the fabrication of a transistor, a capacitor, and three contacts: one each to the bit line, the word line, and the reference voltage. There is continuous pressure to decrease the size of individual cells and to increase memory cell density to allow more memory to be squeezed onto a single memory chip. Limitations on cell size reduction include the passage of both active and passive word lines through the cell, the size of the cell capacitor, and the compatibility of array devices with non-array devices. With device scaling, charge carriers experience a larger electric field, forming defects at the channel/gate interface, and decreases in drain current. In addition, device scaling also contributes to a phenomenon referred to as “oxide charge”, which develops when silicon-hydrogen bonds are broken at the channel-gate interface dure to frequent and high energy charge-discharge cycles. Such an oxide charge may form a dangling silicon bond that forms an interface trap region, further reducing drain current across gate/channel interface.

Attempts have been made to reduce such defects by passivating the channel prior to formation of the gate. However, such passivation results in excessive doping, and thus a channel with a threshold voltage unsuitably high for device operation. Efforts were also conducted to dope adjacent materials, such as a dielectric material, and diffuse the dopant into the target region. Such attempts resulted in adjacent materials with unacceptably high dopant levels as well as channel-gate interfaces with poor passivation, as the dopant was unable to effectively migrate to the target region, even at high doping levels.

Surprisingly, the present technology has found that by carefully controlling the formation of an adjacent dielectric material, such as an interlayer dielectric, a film having an increased density and/or reduced defects may be formed. The produced films having increased density and/or reduced defects provide for highly efficient migration of a dopant to a target region. Namely, the present technology has found that by controlling deposition conditions, an oxide film, such as an interlayer dielectric, may be formed that provides excellent permeability to a dopant material. In addition, due at least in part to the effective permeability of the dopant, the present technology may provide target doping concentrations that allow for excellent passivation of a gate-channel interface while exhibiting little to no decrease in threshold voltage, such as evidenced by little to no increase in negative-bias temperature instability.

After describing general aspects of a chamber configured to perform operations according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of semiconductor processing chambers and operations.

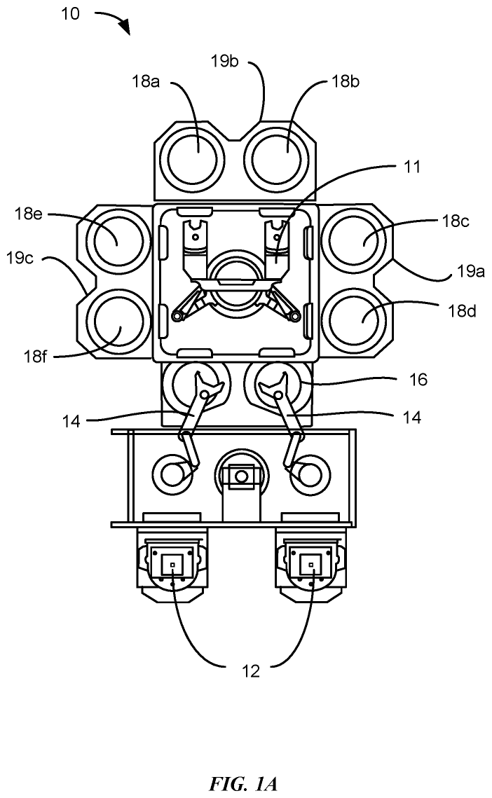

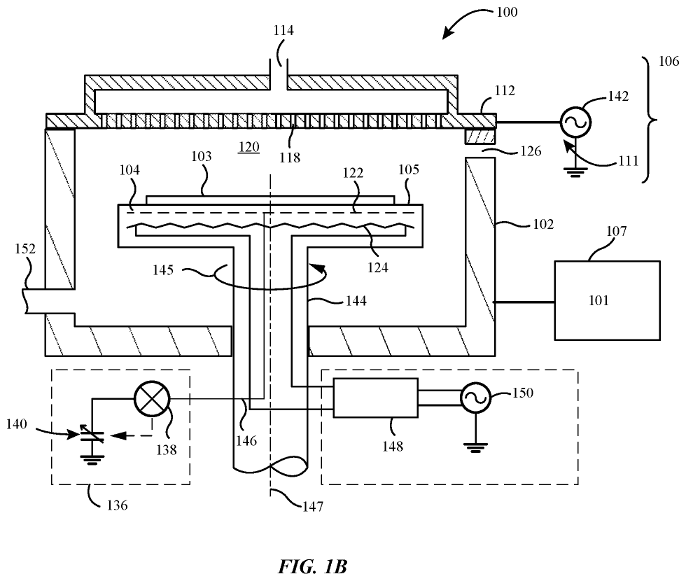

FIG. 1A shows a top plan view of one embodiment of a processing system 10 of deposition, treating, etching, baking, and curing chambers according to embodiments. In the figure, a pair of front opening unified pods 12 supply substrates of a variety of sizes that are received by robotic arms 14 and placed into a low pressure holding area 16 before being placed into one of the semiconductor processing chambers 18a-f, positioned in tandem sections 19a-c. A second robotic arm 11 may be used to transport the substrate wafers from the holding area 16 to the semiconductor processing chambers 18a-f and back. Each semiconductor processing chamber 18a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, plasma treatments, annealing, ashing, etc.

The semiconductor processing chambers 18a-f may include one or more system components for depositing, plasma treating, curing and/or etching a dielectric or other film on the substrate. In one configuration, two pairs of the semiconductor processing chambers, e.g., 18c-d and 18e-f, may be used to deposit dielectric material on the substrate, and the third pair of semiconductor processing chambers, e.g., 18a-b, may be used to treat the deposited dielectric. In another configuration, all three pairs of chambers, e.g., 18a-f, may be configured to deposit and treat stacks of alternating dielectric films on the substrate. Any one or more of the processes described may be carried out in chambers separated from the fabrication system shown in different embodiments. It will be appreciated that additional configurations of deposition, treating, etching, annealing, and curing chambers for dielectric films are contemplated by system 10.

FIG. 1B shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 144 of the substrate support 104 may be locate, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

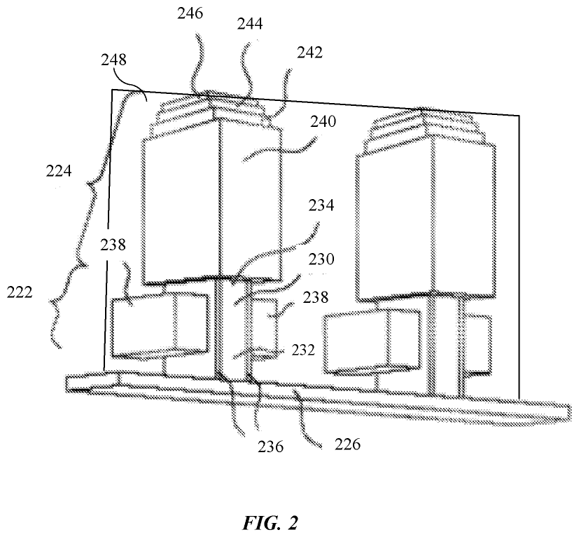

FIG. 2 illustrates a perspective view of an exemplary 3D device that may utilize the methods and processes discussed herein. However, it should be clear that the present technology is applicable to other 3D devices, as well as devices that include channel-gate defects and that may utilize one or more dielectric materials as discussed herein. Nonetheless, for illustration only, FIG. 2 may illustrate a vertical 3D DRAM device according to embodiments of the present disclosure. FIG. 2 depicts two 3D DRAM cells that each include a vertical channel device (e.g., a transistor). To avoid unnecessarily obscuring aspects of the figures, one DRAM cell is labeled with reference numbers, and a person having ordinary skill in the art will readily understand common components in the other DRAM cell of FIG. 2. Additionally, the structures illustrated in FIG. 2 may omit various components to more clearly illustrate various features. A person having ordinary skill in the art will readily understand other components that may be included in similar structures.

A DRAM cell includes an access transistor 222 and a capacitor 224. The access transistor 222 includes a semiconductor material 230 that is disposed on and extends vertically from a bit line contact 226. The semiconductor material 230 forms the active region of the access transistor 222 and includes a channel region of the access transistor 222. A drain region 232 and a source region 234 are disposed in the semiconductor material 230 with the channel region between the drain region 232 and the source region 234 in the semiconductor material 230. In embodiments, the drain region 232 may be disposed proximate to and/or adjoining the bit line contact 226, and the source region 234 may be spaced apart from the bit line contact 226. A gate dielectric layer 236 is disposed on the semiconductor material 230 (e.g., on sidewall surfaces of the semiconductor material 230), and a gate electrode 238 is disposed on the gate dielectric layer 236. FIG. 2 illustrates a cut-away portion of the access transistor 222 to illustrate the semiconductor material 230. As will be readily understood from subsequent description, the gate dielectric layer 236 can be disposed laterally encircling the semiconductor material 230, and the gate electrode 238 can be disposed laterally encircling the gate dielectric layer 236, or the gate dielectric layer 236 and gate dielectric layer may extend vertically on opposed sides of semiconductor material 230, as well as other configurations as known in the art.

The capacitor 224 includes an outer plate 240, a capacitor dielectric layer 242, and an inner plate 244. The outer plate 240 is a conductive material, such as a metal or metal-containing material. The outer plate 240 generally has the shape of a single-capped vertical cylinder, single-capped rectangular prism, or the like. The outer plate 240 generally extends vertically from the access transistor 222 and has a capped end that contacts the source region 234 of the access transistor 222 to electrically connect the source region 234 to the capacitor 224. The capacitor dielectric layer 242 is a dielectric material that is disposed along interior surfaces of the outer plate 240. The dielectric material of the capacitor dielectric layer 242 can be a high-k dielectric material (e.g., having a k-value greater than 4.0). The inner plate 244 may be a conductive material, such as a metal or metal-containing material, and is disposed on the capacitor dielectric layer 242 and fills a remaining interior portion of the outer plate 240. A power supply contact 246 (e.g., a ground contact) is disposed laterally and contacts the inner plate 244 of the capacitor 224. In addition, an interlayer dielectric 248 may encapsulate all or a portion of the DRAM cell, and may include one or more dielectric materials that will be discussed in greater detail below.

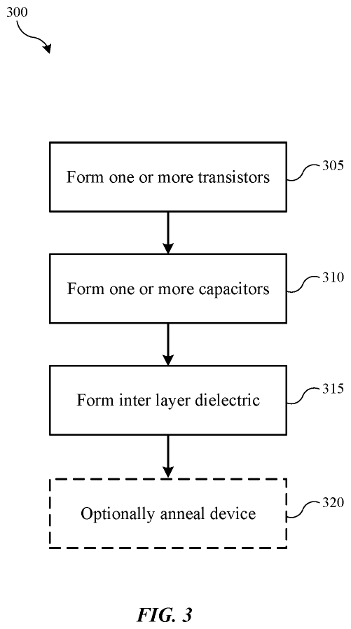

FIG. 3 shows exemplary operations in a method 300 for forming a semiconductor structure according to embodiments of the present technology. Method 300 may include one or more operations prior to the initiation of the method, including front-end processing, deposition, etching, polishing, cleaning, or any other operations that may be performed prior to the described operations. For example, the method may begin after a number of layers have been deposited and/or formed, such as for producing 3D DRAM structures, or any one or more of the 3D structures discussed above. However, as explained above, it is to be understood that the figures illustrate just one exemplary process in which processes according to embodiments of the present technology may be employed, and the description is not intended to limit the technology to this process or structure alone. Some or all of the operations may be performed in chambers or system tools as previously described, or may be performed in different chambers on the same system tool, which may include the chamber in which the operations of method 300 may be performed.

Method 300 may include additional operations prior to initiation of the listed operations. For example, additional processing operations may include forming structures on a substrate, which may include both forming and removing material. Prior processing operations may be performed in the chamber in which method 300 may be performed, or processing may be performed in one or more other semiconductor processing chambers prior to delivering the substrate into the semiconductor processing chamber in which method 300 may be performed. Regardless, method 300 may optionally include delivering a substrate to a processing region of a semiconductor processing chamber, such as semiconductor processing chamber 100 described above, or other chambers that may include components as described above. The substrate may be deposited on a substrate support, which may be a pedestal such as substrate support 104, and which may reside in a processing region of the chamber, such as processing volume 120 described above.

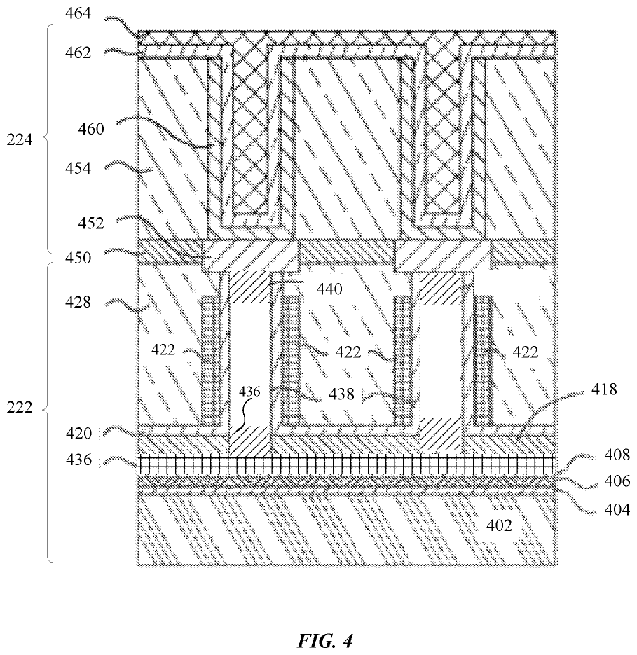

As illustrated in FIG. 4 substrate 402 which may be any number of materials, such as a base wafer or substrate made of silicon or silicon-containing materials, germanium, other substrate materials, as well as one or more materials that may be formed overlying the substrate during semiconductor processing, is provided to a processing chamber, such as processing chamber 100. In embodiments, the substrate 402 may include bulk substrates, epitaxially grown substrates, and/or silicon on insulator wafer. As used herein, the term “semiconductor substrate” refers to a substrate in which the entirety of the substrate is formed from a semiconductor material. The semiconductor substrate may include any suitable semiconducting material and/or combinations of semiconducting materials for forming a semiconductor structure. For example, the semiconducting layer may include one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 402 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 402 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

In embodiments, prior processing may form one or more materials on the substrate 402. For example, the illustrated embodiment may contain one or more transistor 222 features, formed at operation 305. For instance, in embodiments, a film stack may be deposited on substrate 402. In embodiments, the film stack may include a first barrier layer 404, a conductive layer 406, and/or a second barrier layer 408, as well as other layers as known in the art, or no film stack may be utilized. The first barrier layer 404 may be deposited on the substrate 402. The conductive layer 406 may be deposited on the first barrier layer 404. The second barrier layer 408 may be deposited on the conductive layer 406. The semiconductor material may be deposited on the second barrier layer 408. The first barrier layer 404, conductive layer 406, and/or second barrier layer 408 may be deposited and/or doped by any appropriate deposition process, such as chemical vapor deposition (CVD), plasma enhanced chemical vapor deposition (PECVD), atomic layer deposition (ALD), physical vapor deposition (PVD), or the like. In embodiments, the first barrier layer 404 and/or the second barrier layer 408 are each titanium nitride (TiN), tantalum nitride (TaN), or the like. In embodiments, the conductive layer 406 is a metal or metal-containing material, such as tungsten (W) or the like. The first barrier layer 404, conductive layer 406, and/or second barrier layer 408 may form all or part of a bit line contact.

Nonetheless, as illustrated, one or more channels 438 formed from one or more semiconductor materials may be disposed over second barrier layer 408. The semiconductor material of channel 438 may extend vertically from second barrier layer 408, or may extend horizontally as discussed above (e.g. may form a unit pair of a horizontally extending channel device). Each channel 438 may contain opposed source/drain regions 436, which may be doped regions of the channel 438 semiconductor material. In embodiments, the channel 438 may be formed from silicon, or one or more of the semiconductor materials discussed above.

Regardless of the channel 438 material selected, a gate dielectric 420 and gate electrode 422 may be formed around or along all or a portion of channel 438, separated from second barrier layer 408 via spacer 418. While not shown in FIG. 4, spacer 418 may contact substrate 402 between adjacent patterned features (e.g. between respective bit lines). In embodiments, the gate dielectric 420 may be any dielectric material and may be deposited utilizing one or more processes, such as PECVD, ALD, CVD, or another deposition process. Nonetheless, in embodiments, the gate dielectric may be silicon oxide.

Gate electrodes 422 may be formed along the surface of the gate dielectric layer 420. Each of the formed gate electrodes 422 may be disposed on a portion of the gate dielectric layer 420 that is on sidewalls of a respective channel 438 such that the respective gate electrode 422 laterally encircles the channel 438 or extends along opposing sides of the channel 438. The material of the gate electrodes 422 can be deposited by PECVD, ALD, CVD, or another deposition process as known in the art. The material of the gate electrodes 422 can be a single material or multiple different materials (e.g., in multiple different layers.) In some examples, the gate electrodes 122 are a metal or metal-containing material, such as tungsten (W) or the like.

In embodiments, a dielectric layer 428 is deposited on the gate dielectric layer 420 and gate electrodes 422. The dielectric layer 428 can be any dielectric layer, such as silicon oxide, borophosphosilicate glass (BPSG), phosphosilicate glass (PSG), or the like.

Nonetheless, at operation 310, one or more capacitors 224 or features thereof may be formed over transistor 222. For instance, an etch barrier layer 450 and a contact pad 452 may be formed over transistor 222, such that the contact pad 452 contacts a source/drain region 436 of the transistor. The conductive pad 452 may include a barrier layer, such as titanium nitride (TiN), tantalum nitride (TiN), or the like, and a metal or metal-containing material on the barrier layer, such as tungsten (W), aluminum (Al), copper (Cu), or the like. The conductive pad 452 may form an ohmic contact with the respective channel 438.

In embodiments, an inter layer dielectric (ILD) layer 454 is formed at operation 315 on the etch stop layer 450 and the conductive pads 452. The ILD layer 454 can be or contain one or more dielectric material, and can be deposited by one or more deposition processes, as will be discussed in greater detail. The ILD layer 454 may be patterned with an opening to a respective conductive pad 452.

A capacitor 224 may be formed in the respective opening through the ILD layer 454. The capacitor includes an outer plate 460, a capacitor dielectric layer 462, and an inner plate 464. The outer plates 460 may be formed along surfaces of the openings through the ILD layer 454. The capacitor dielectric 462 may be formed on the inner surfaces of the respective outer plates 460. The capacitor dielectric layer 462 may extend between the openings on the top surface of the ILD layer 454. Inner plates 464 may be formed on outer plates 460 and may form terminals of the respective device that are electrically connected to a power supply node (e.g., a ground node), as discussed in FIG. 3. In embodiments, the outer plates 460 and/or the inner plates 464 may be any conductive material, such as a metal or metal-containing material, such as titanium nitride (TiN). In embodiments, the capacitor dielectric layer 462 may be any dielectric material, and further, may be a high-k dielectric material (e.g., having a k-value of greater than 4.0).

Notwithstanding the capacitor 224 formed, the interlayer dielectric 454 may be carefully formed according to the present technology. Namely, as discussed above, the present technology has surprisingly found that improved dopant migration is achieved alone or in conjunction with highly accurate target doping levels of the channel-gate interface due to target doping concentrations during layer formation. Without wishing to be bound by theory, it is believed that by forming the interlayer dielectric 454 according to the present technology, an interlayer dielectric with little to no film variation is formed, allowing improved migration due at least in part to reduced gettering sites in the interlayer dielectric 454. As discussed above, in prior devices, dielectric layers, such as interlayer dielectric, contained high levels of gettering sites (which may also be referred to as “interface traps”) which prevented the dopant from migrating through the dielectric layer, as the dopant became “trapped” in the gettering sites. Thus, by utilizing targeted temperature and deposition conditions, such as a high HF concentration, improved mobility through the dielectric layer may be achieved due to the uniformly dense material.

In embodiments, doping the interlayer dielectric 454 with deuterium (D) during formation of the interlayer dielectric 454 advantageously allows the deuterium to act as a passivating agent for stabilizing and increasing the reliability of the channel-gate interface. Without intending to be bound by theory, it is believed that films containing deuterium and/or hydrogen enable chemical passivation of unsatisfied valence bonds on immobilized atoms in a solid matrix. Namely, deuterium may form a stronger and more stable chemical passivation of many atomic elements, compared to chemical passivation with hydrogen. For example in solid materials and solid interfaces created with common silicon-based solid materials such as crystalline silicon, polycrystalline silicon, amorphous silicon, silicon oxide, silicon nitride, and silicon carbide, deuterium forms stronger chemical bonds to silicon atoms compared to hydrogen chemical bonds to silicon atoms. Compared to hydrogen-passivated silicon materials and interfaces, it has been found that deuterium-passivated silicon materials and interfaces are more electrically stable and reliable with higher applied voltages, with higher applied electric currents, with electromagnetic radiation exposures at shorter wavelengths and higher intensity, and at higher temperatures. Nonetheless, in embodiments, other dopants may be contemplated, such as tritium, or other dopants having similar properties to hydrogen but with increased bond strength and/or decreased desorption rates.

In embodiments, materials and interface reliability improvements with deuterium chemical passivation are possible in other common materials systems, such as, but not limited to, III-V and II-VI semiconductors: gallium arsenide, aluminum arsenide, aluminum-gallium arsenide, gallium nitride, aluminum nitride, aluminum-gallium nitride, zinc-oxide, cadmium oxide, cadmium telluride, cadmium-selenide, magnesium-oxide, as well as oxide and nitride derivatives of III-V and II-VI semiconductors. Thus, while silicon and silicon oxide are reference herein, it should be understood that the methods and systems discussed herein are also suitable for passivating other semiconductor materials.

Nonetheless, in embodiments, the deuterium may be incorporated into one or more dielectric layers, such as interlayer dielectric 454. The one or more dielectric layers may include any dielectric material as known in the art, such as an electrical insulator material that can be polarized by an applied electric field. In one or more embodiments, the dielectric material includes, but is not limited to, oxides, e.g., SiO₂, Ta₂O₅, Al₂O₃, nitrides, e.g., Si₃N₄, and barium strontium titanate (BST). In one or more embodiments, the dielectric material may include silicon dioxide (SiO₂). In embodiments, the film composition may be non-stoichiometric relative to the ideal molecular formula. For example, in some embodiments, the dielectric material includes, but is not limited to, oxides (e.g., silicon oxide, tantalum oxide, aluminum oxide), nitrides (e.g., silicon nitride (SiN)), carbides (e.g. silicon carbide (SiC)), silicon carbo nitride (SiCN), oxycarbides (e.g. silicon oxycarbide (SiOC)), oxynitrocarbides (e.g. silicon oxycarbonitride (SiNCO)), and barium strontium titanate (BST). However, as discussed above, in embodiments, the dielectric material, such as interlayer dielectric 454 may be or include silicon dioxide. Furthermore, while the methods and systems discussed herein are discussed in regards to interlayer dielectric 454, it should be understood that the incorporation a dopant as discussed herein may be utilized in other dielectric layers in one or more devices. As will be discussed in greater detail below, it may be desired to dope the interlayer dielectric 454 in order to achieve high levels of diffusion without negatively effecting the film properties of the channel. Namely, as noted above, when directly doping the channel, unacceptably high threshold voltages are exhibited, which does not occur or occurs to a significantly lesser extent when doping an adjacent material.

Regardless of the material or layer(s) selected, operation 315 may include forming the dielectric layer, such as interlayer dielectric 454 in the presence of a deuterium-containing precursor. In embodiments, the deuterium-containing precursor may be pulsed or co-flowed into the processing chamber with a flow gas or carrier gas. In other embodiments, the deuterium-containing precursor is pulsed into the processing chamber in the absence of a carrier gas. As used herein, the term “carrier gas” refers to a fluid (either gas or liquid) that can move a precursor molecule from one location to another. For example, a carrier gas can be a liquid that moves molecules from a solid precursor in an ampoule to an aerosolizer. In some embodiments, a carrier gas is an inert gas. In one or more embodiments, a carrier gas is one or more of argon (Ar), helium (He), xenon (Xe), or nitrogen (N₂). In embodiments, the deuterium-containing precursor may include one or more of molecular deuterium (D₂), deuterated water (D₂O), DH (deuterium-hydrogen) or HDO (deuterium-hydrogen oxide). Moreover, in embodiments, the plasma may also include one or more of argon (Ar), helium (He), hydrogen (H₂), nitrogen (N₂), oxygen (O₂), ammonia (NH₃), or nitrogen trifluoride (NF₃).

In embodiments, films and/or layers containing deuterium and silicon, and/or one or more other materials discussed above, may be deposited by plasma enhanced chemical vapor deposition (PECVD), chemical vapor deposition (CVD), or atomic layer deposition (ALD), as well as other methods as known in the art, using chemical precursors and inert gases. In one or more embodiments, the deposition method passivates dangling silicon bonds by introducing a dopant, such as deuterium, into a film, which allows migration of the deuterium to the target are (e.g., the channel-gate interface in the illustrated example). Thus, the present technology provides for targeted dopant levels while preventing changes in the film quality. For example, in one or more embodiments, films including, but not limited to, SiH_{Y}D_{Z}, SiO_{X1}H_{Y}D_{Z}, SiN_{X2}H_{Y}D_{Z}, SiC_{X3}H_{Y}D_{Z}, SiO_{X1}N_{X2}C_{X3}H_{Y}D, are deposited on a substrate surface. In one or more embodiments, deuterium-containing precursors includes one of more of D₂, D₂O, SiD₄, Si₂D₆. In one or more embodiments, the deuterium-containing precursors may be combined, or co-flowed, with one or more silicon precursor selected from one or more of SiH₄, Si₂H₆, SiCl₄, SiHCl₃, SiH₂Cl₂, SiHCl₃, Si₂Cl₆, SiF₄, SiBr₄, TEOS, TDMAS, BTBAS, BDEAS, and the like. Nonetheless, in embodiments, the deuterium-containing precursor may be combined or flowed with tetraethyl orthosilicate (TEOS), alone or in combination with one or more precursors.

In one or more embodiments, the deuterium-containing precursors may be combined, or co-flowed, with one or more of oxygen (O₂), ozone (O₃), or water (H₂O). In one or more embodiments, the deuterium-containing precursors may be combined, or co-flowed, with one or more of nitrogen (N₂), or ammonia NH₃ to form a deuterium-containing nitride film. In one or more embodiments, the deuterium-containing precursors may be combined, or co-flowed, with one or more of methane (CH₄), or ethane (C₂H₂) to form deuterium-containing carbon films. In one or more embodiments, the deuterium-containing precursors may be combined, or co-flowed, with hydrogen (H₂). In one or more embodiments, the deuterium-containing precursors may be combined, or co-flowed, with one or more inert gas including, but not limited to, argon (Ar), or helium (He) to form a deuterium-containing film. In one or more embodiments, deposition processes may include thermal, plasma, and/or optical sources to activate precursors and to control chemical reaction rates.

Nonetheless, in embodiments, interlayer dielectric 454 may be formed with a relatively high temperature. Namely, the present technology has found that increased temperature during deposition may contribute to decreased instances of gettering sites and/or increased density in the interlayer dielectric 454. Thus, in embodiments, the interlayer dielectric 454 may be formed at a temperature of greater than or about 325° C., such as greater than or about 330° C., such as greater than or about 335° C., such as greater than or about 340° C., such as greater than or about 345° C., such as greater than or about 350° C., such as greater than or about 355° C., such as greater than or about 360° C., such as greater than or about 365° C., such as greater than or about 370° C., such as greater than or about 375° C., such as greater than or about 380° C., such as greater than or about 385° C., such as greater than or about 390° C., such as greater than or about 395° C., such as up to about 400° C., or greater, or any ranges or values therebetween.

Moreover, the present technology has surprisingly found that utilizing a high frequency RF plasma at tailored power levels for formation of interlayer dielectric 454 may also improve the presence of gettering sites and/or allow for increased density in the interlayer dielectric 454. Thus, in embodiments, the plasma processes discussed above, such as flowing of the silicon-containing precursor, deuterium-containing precursor, and additional processes gasses, may be generated at a high frequency utilizing a high frequency generator, such as a generator operating at greater than or about 13.56 MHz, or other high frequencies as known in the art. Moreover, the high frequency RF plasma may be generated at a plasma power of greater than or about 800 watts, such as greater than or about 850 watts, such as greater than or about 900 watts, such as greater than or about 950 watts, such as greater than or about 1000 watts, such as greater than or about 1050 watts, such as greater than or about 1100 watts, such as greater than or about 1150 watts, such as greater than or about 1200 watts, or any ranges or values therebetween.

The pressure within the semiconductor processing chamber may also affect the operations performed. In embodiments, the pressure may be maintained at less than about 100 Torr. Accordingly, the pressure may be maintained at less than or about 50 Torr, less than or about 40 Torr, less than or about 30 Torr, less than or about 25 Torr, less than or about 20 Torr, less than or about 18 Torr, less than or about 16 Torr, less than or about 14 Torr, less than or about 12 Torr, less than or about 10 Torr, less than or about 8 Torr, less than or about 6 Torr, less than or about 4 Torr, less than or about 2 Torr, or less, or any ranges or values therebetween. The pressure may also be maintained at any pressure within these ranges, within smaller ranges encompassed by these ranges, or between any of these ranges.

The flow rate of one or more of the silicon-containing precursor, deuterium-containing precursor, plasma processes precursors, or a combination thereof may be between 1 sccm and 10,000 sccm, for example, from about 400 sccm to about 2,000 sccm. The processing time may be between 1 min and 10 min, such as 3 min. The pressure within the processing chamber may be varied during the vapor phase process. For example, the pressure may be varied between 50 Torr and 500 Torr.

Furthermore, the present technology has surprisingly found that by carefully tailoring the ratio of the deuterium-containing precursor to the silicon-containing precursor, a high percentage of deuterium may migrate to the channel-gate region without exhibiting large increases of deuterium in the interlayer dielectric 454. Thus, in embodiments, the deuterium-containing precursor may be introduced into the processing region at a ratio with the silicon-containing precursor (such as TEOS in embodiments) of greater than or about 0.9:1, such as greater than or about 1:1, such as greater than or about 1.1:1, such as greater than or about 1.2:1, such as greater than or about 1.3:1, such as greater than or about 1.4:1, such as greater than or about 1.5:1, such as greater than or about 1.6:1, such as greater than or about 1.7:1, such as greater than or about 1.8:1, such as greater than or about 1.9:1, such as greater than or about 2:1, such as greater than or about 2.2:1, such as greater than or about 2.4:1, such as greater than or about 2.6:1, such as greater than or about 2.8:1, such as greater than or about 3:1, such as greater than or about 3.2:1, such as greater than or about 3.4:1, such as greater than or about 3.6:1, such as greater than or about 3.8:1, such as greater than or about 4:1, such as greater than or about 4.2:1, such as greater than or about 4.4:1, such as greater than or about 4.5:1, such as greater than or about 4.6:1, such as greater than or about 4.8:1, such up to about 5:1, or greater, or any ranges or values therebetween. By utilizing such ratios, excellent stress and deposition rate may be maintained while also maintaining desirable levels of deuterium in the interlayer dielectric 454.

By utilizing such ratios, an among of deuterium in the interlayer dielectric 454 may be from about 0.1% to about 1% by weight of the interlayer dielectric, such as greater than or about 0.15 wt. %, such as greater than or about 0.2 wt. %, such as greater than or about 0.25 wt. %, such as greater than or about 0.3 wt. %, such as greater than or about 0.35 wt. %, such as greater than or about 0.4 wt. %, such as greater than or about 0.45 wt. %, such as greater than or about 0.5 wt. %, such as greater than or about 0.55 wt. %, such as greater than or about 0.6 wt. %, such as greater than or about 0.65 wt. %, such as greater than or about 0.7 wt. %, such as greater than or about 0.75 wt. %, such as greater than or about 0.8 wt. %, such as greater than or about 0.85%, such as greater than or about 0.9 wt. %, such as greater than or about 0.95 wt. %, or any ranges or values therebetween.

In embodiments, optional operation 320 may include heat treating or annealing the semiconductor structure after forming the deuterium-containing dielectric in order to encourage migration of the deuterium to the target region. However, in embodiments, the passivation of the target region may be achieved during processing, and may not require a separate anneal or heat treatment operation.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. “About” and/or “approximately” as used herein and in the appended claims when referring to a measurable value such as an amount, a temporal duration, and the like, encompasses variations of ±20%, ±10%, ±5%, or ±0.1% from the specified value, as such variations are appropriate to in the context of the systems, devices, circuits, methods, and other implementations described herein. “Substantially” as used herein and in the appended claims when referring to a measurable value such as an amount, a temporal duration, a physical attribute (such as frequency), and the like, also encompasses variations of ±20%, ±10%, ±5%, or ±0.1% from the specified value, as such variations are appropriate to in the context of the systems, devices, circuits, methods, and other implementations described herein.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of modifying a target region, comprising:
flowing a deuterium-containing precursor and a silicon-containing precursor into a processing region of a processing chamber;
contacting a semiconductor device disposed in the processing region with the deuterium-containing precursor and the silicon-containing precursor;
forming a deuterium-containing dielectric film over or on the semiconductor device at a processing temperature of greater than or about 350° C.; and
passivating the target region with deuterium from the deuterium-containing dielectric film;
wherein the deuterium-containing dielectric film is spaced apart from or adjacent to the target region.

2. The method of claim 1, wherein the deuterium-containing precursor comprises one or more of D₂, D₂O, DH (deuterium-hydrogen) or HDO (deuterium-hydrogen oxide).

3. The method of claim 1, wherein the deuterium-containing precursor and the silicon-containing precursor are flowed utilizing a plasma process, wherein the plasma further comprises one or more of argon (Ar), helium (He), hydrogen (H2), nitrogen (N2), oxygen (O2), ammonia (NH3), or nitrogen fluoride (NF3).

4. The semiconductor processing method of claim 1, wherein the silicon-containing precursor comprise one or more of silane (SiH₄), disilane (Si₂H₆), silicon tetrachloride (SiCl₄), trichlorosilane (SiHCl₃), dichlorosilane (SiH₂Cl₂), hexachlorodisilane (Si₂Cl₆), silicon tetrafluoride (SiF₄), silicon tetrabromide (SiBr₄), tetraethyl orthosilicate (TEOS), tris(dimethylamino)silane (TDMAS), bis(t-butylamino)silane (BTBAS), bis(diethylamion)silane (BDEAS), or a combination thereof.

5. The method of claim 1, wherein the deuterium-containing dielectric film is formed over or on the semiconductor device at a processing temperature of greater than or about 400° C.

6. The method of claim 1, wherein the deuterium-containing dielectric film is formed with a ratio of the deuterium-containing precursor to the silicon-containing precursor of greater than or about 0.9:1.

7. The method of claim 6, wherein the ratio of the deuterium-containing precursor to the silicon-containing precursor of greater than or about 1.5:1.

8. The method of claim 7, wherein the ratio of the deuterium-containing precursor to the silicon-containing precursor of greater than or about 4:1.

9. The method of claim 1, wherein the deuterium-containing dielectric film comprises from about 0.1 wt. % to about 1 wt. % deuterium, based upon the weight of the deuterium-containing dielectric film.

10. The method of claim 1, wherein the target region comprises a channel-gate interface.

11. The method of claim 1, wherein the deuterium-containing dielectric film comprises an interlayer dielectric.

12. The method of claim 3, wherein the plasma comprises a high frequency plasma and a plasma power of greater than or about 800 watts.

13. A semiconductor processing method, comprising:
forming a semiconductor device comprising one or more transistors and one or more capacitors over the one or more transistors in a processing region of a processing chamber;
flowing a deuterium-containing precursor and a silicon-containing precursor into the processing region of the processing chamber;
contacting the semiconductor device disposed in the processing region with the deuterium-containing precursor and the silicon-containing precursor;
forming a deuterium-containing dielectric film over or on the semiconductor device at a processing temperature of greater than or about 350° C.; and
passivating a target region of the semiconductor device with deuterium from the deuterium-containing dielectric film;
wherein the deuterium-containing dielectric film is spaced apart from or adjacent to the target region.

14. The semiconductor processing method of claim 13, wherein the semiconductor device comprises a three-dimensional (3D) semiconductor device.

15. The semiconductor processing method of claim 14, wherein three-dimensional device comprises a three-dimensional dynamic random access memory (3D DRAM) device.

16. The semiconductor processing method of claim 13, wherein the target region comprises a channel-gate interface and the deuterium-containing dielectric film comprises an interlayer dielectric.

17. The semiconductor processing method of claim 13, wherein the silicon-containing precursor comprises tetraethyl orthosilicate, and wherein the deuterium-containing dielectric film is formed with a ratio of the deuterium-containing precursor to the silicon-containing precursor of greater than or about 0.9:1.

18. The semiconductor processing method of claim 13, wherein the deuterium-containing precursor and the silicon-containing precursor are flowed utilizing a plasma process, wherein the plasma comprises a high frequency plasma and a plasma power of greater than or about 800 watts.

19. A method of forming a three-dimensional dynamic random-access memory (3D DRAM) device, comprising:
forming a semiconductor structure comprising one or more transistors and one or more capacitors over the one or more transistors in a processing region of a processing chamber, wherein the one or more transistors comprises a channel and a gate;
flowing a deuterium-containing precursor and a silicon-containing precursor into the processing region of the processing chamber;
contacting the semiconductor structure disposed in the processing region with the deuterium-containing precursor and the silicon-containing precursor;
forming a deuterium-containing dielectric film over or on the semiconductor structure at a processing temperature of greater than or about 350° C.; and
passivating a channel-gate interface region of the semiconductor structure with deuterium from the deuterium-containing dielectric film.

20. The method of claim 19, wherein the deuterium-containing dielectric film is an interlayer dielectric overlying the one or more transistors and/or the one or more capacitors.
